(19) United States
(12) Patent Application Publication
(10) Pub. No.: US 2024/0103369 A1
(43) Pub. Date: Mar. 28, 2024

(54) RESIST UNDERLAYER FILM FORMATION COMPOSITION

(71) Applicant: NISSAN CHEMICAL CORPORATION, Tokyo (JP)

(72) Inventors: Masahisa ENDO, Toyama-shi (JP); Hayato HATTORI, Toyama-shi (JP); Yuki MITSUTAKE, Toyama-shi (JP); Hirokazu NISHIMAKI, Toyama-shi (JP)

(73) Assignee: NISSAN CHEMICAL CORPORATION, Tokyo (JP)

(21) Appl. No.: 18/268,800

(22) PCT Filed: Dec. 16, 2021
(86) PCT No.: PCT/JP2021/046575

§ 371 Date: Jun. 21, 2023

(30) Foreign Application Priority Data
Dec. 21, 2020 (JP) 2020-211449

(51) Int. Cl. G03F 7/039; G03F 7/038; G03F 7/16

(52) U.S. Cl. CPC G03F 7/0395; G03F 7/0382; G03F 7/0397; G03F 7/168

(57) ABSTRACT

A resist underlayer film-forming composition that exhibits a high etching resistance, a favorable dry etching rate ratio and optical constant, and can form a film exhibiting a good coatability even to a so-called uneven substrate, providing a small difference in film thickness after embedding, and having planarity and a superior hardness; a resist underlayer film formed from the resist underlayer film-forming composition; and a method of producing a semiconductor device. The composition including a reaction product between a compound of the following Formula (1) or (2) and a compound of the following Formula (3), and a solvent:

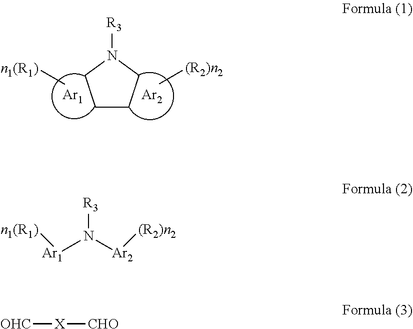

### TECHNICAL FIELD

The present invention relates to a resist underlayer film-forming composition that exhibits an excellent embedding property, a favorable dry etching rate ratio and optical constant, and can form a resist underlayer film exhibiting a good coatability even to a so-called uneven substrate and having planarity and a superior hardness; a resist underlayer film formed from the resist underlayer film-forming composition; and a method of producing a semiconductor device.

### BACKGROUND ART

In recent years, resist underlayer film materials for multi-layer resist processes have been required to function as an anti-reflective coating, particularly against exposure light of short wavelength, to have an appropriate optical constant, and to exhibit an etching resistance during substrate processing. Thus, a proposal has been made to use a polymer having a repeating unit containing a benzene ring (Patent Document 1).

### PRIOR ART DOCUMENTS

### Patent Documents

Patent Document 1: JP 2004-354554 A

### SUMMARY OF THE INVENTION

### Problems to be Solved by the Invention

There has been known a lithographic process wherein at least two resist underlayer films are formed, and the resist underlayer films are used as mask materials, in order to achieve a decrease in thickness of a resist layer required in association with the formation of a finer resist pattern. This process involves formation of at least one layer of organic film (lower-layer organic film) and at least one layer of inorganic underlayer film on a semiconductor substrate; patterning of the inorganic underlayer film by using, as a mask, a resist pattern formed on an upper-layer resist film; and patterning of the lower-layer organic film by using the pattern as a mask. This process can form a pattern having a high aspect ratio. The materials for forming the aforementioned at least two layers are, for example, a combination of an organic resin (e.g., acrylic resin or novolac resin) and an inorganic material (e.g., silicon resin (e.g., organopolysiloxane) or an inorganic silicon compound (e.g., SiON or SiO₂)). In recent years, a double patterning technique (including two lithographic steps and two etching steps) has also been widely used for obtaining one pattern, wherein the aforementioned multi-layer process is used in each step. In this case, the organic film formed after formation of the first pattern is required to have a property of flattening the step.

However, a so-called uneven substrate in which a resist pattern formed on a to-be-processed substrate has a difference in level or in denseness, poses problems in that the substrate is insufficiently coated with a resist underlayer film-forming composition, and a flat film is difficult to be formed due to a large difference in film thickness after embedding.

The present invention has been made for solving the aforementioned problems, and an object of the present invention is to provide a resist underlayer film-forming composition that exhibits a high etching resistance, a favorable dry etching rate ratio and optical constant, and can form a film exhibiting a good coatability even to a so-called uneven substrate, providing a small difference in film thickness after embedding, and having planarity and a superior hardness. Another object of the present invention is to provide a resist underlayer film formed from the resist underlayer film-forming composition, and a method of producing a semiconductor device.

### Means for Solving the Problems

The present invention encompasses the followings.
[1] A resist underlayer film-forming composition comprising a reaction product between a compound of the following Formula (1) or (2) and a compound of the following Formula (3), and a solvent:

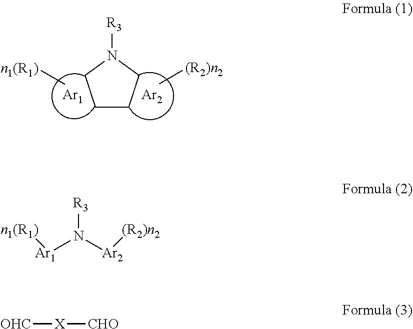

(in Formula (1) or (2), Ar₁ and Ar₂ are each independently a benzene ring or naphthalene ring substitutable with R₁ or R₂; R₁ and R₂ are each a hydrogen atom, a halogen atom, a nitro group, an amino group, a hydroxyl group, a C₁₋₁₀ alkyl group, a C₂₋₁₀ alkenyl group, a C₆₋₄₀ aryl group, or any combination of these possibly containing an ether bond, a ketone bond, or an ester bond; R₃ is a hydrogen atom, a C₁₋₁₀ alkyl group, a C₂₋₁₀ alkenyl group, a C₂₋₁₀ alkynyl group, a C₆₋₄₀ aryl group, or any combination of these possibly containing an ether bond, a ketone bond, or an ester bond; and n₁ and n₂ are each an integer of 1 to 3 when Ar₁ and Ar₂ are each a benzene ring, or an integer of 1 to 5 when Ar₁ and Ar₂ are each a naphthalene ring; and
in Formula (3), X is a single bond, a saturated or unsaturated linear or cyclic organic group having a carbon atom number of 1 to 30 and possibly containing a nitrogen atom, an oxygen atom, or a sulfur atom, or a C₆₋₃₀ arylene group).
[2] The resist underlayer film-forming composition according to [1], wherein, in Formula (1) or (2), Ar₁ and Ar₂ are each a benzene ring.
[3] The resist underlayer film-forming composition according to [1] or [2], wherein, in Formula (1), R₁ and R₂ are each a hydrogen atom.
[4] The resist underlayer film-forming composition according to any one of [1] to [3], wherein, in Formula (3), X is a single bond, or a saturated or unsaturated linear or cyclic organic group having a carbon atom number of 1 to 30 and possibly containing a nitrogen atom.
[5] The resist underlayer film-forming composition according to any one of [1] to [3], wherein, in Formula (3), X is a single bond.
[6] The resist underlayer film-forming composition according to any one of [1] to [5], wherein the composition comprises a reaction product between two or more compounds of Formula (1) or (2) and a compound of Formula (3).
[7] The resist underlayer film-forming composition according to any one of [1] to [5], wherein the composition comprises a reaction product between a compound of Formula (1) or (2), an additional aromatic compound other than the compound of Formula (1) or (2) and a compound of Formula (3).
[8] The resist underlayer film-forming composition according to any one of [1] to [7], wherein the composition further comprises a crosslinking agent.
[9] The resist underlayer film-forming composition according to any one of [1] to [8], wherein the composition further comprises an acid and/or an acid generator.

[10] The resist underlayer film-forming composition according to any one of [1] to [9], wherein the solvent has a boiling point of 160° C. or higher.
[11] A resist underlayer film characterized by being a baked product of a coating film formed from the resist underlayer film-forming composition according to any one of [1] to [10].
[12] A method of producing a semiconductor device comprising:
a step of forming, on a semiconductor substrate, a resist underlayer film from the resist underlayer film-forming composition according to any one of [1] to [10];
a step of forming a resist film on the formed resist underlayer film;
a step of irradiating the formed resist film with light or electron beams, and developing the resist film, to thereby form a resist pattern;
a step of etching the resist underlayer film with the formed resist pattern, to thereby form a pattern on the resist underlayer film; and
a step of processing the semiconductor substrate with the patterned resist underlayer film.

### Effects of the Invention

The resist underlayer film-forming composition of the present invention exhibits a high etching resistance, and a favorable dry etching rate ratio and optical constant, and the resist underlayer film formed from the composition exhibits a good coatability even to a so-called uneven substrate, provides a small difference in film thickness after embedding, and has planarity and a superior hardness. Thus, finer substrate processing can be achieved.

In particular, the resist underlayer film-forming composition of the present invention is effective for a lithographic process wherein at least two resist underlayer films are formed for the purpose of decreasing the thickness of a resist film, and the resist underlayer films are used as etching masks.

### MODES FOR CARRYING OUT THE INVENTION

### Resist Underlayer Film-Forming Composition

The resist underlayer film-forming composition of the present invention contains a reaction product between a compound of the following Formula (1) or (2) and a compound of the following Formula (3), and a solvent:

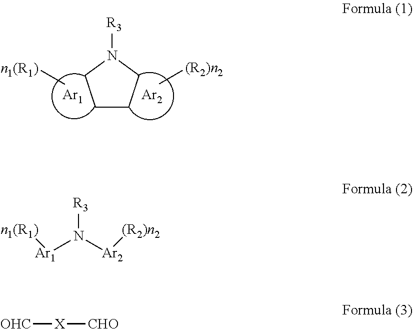

(in Formula (1) or (2), Ar₁ and Ar₂ are each independently a benzene ring or naphthalene ring substitutable with R₁ or R₂; R₁ and R₂ are each a hydrogen atom, a halogen atom, a nitro group, an amino group, a hydroxyl group, a C₁₋₁₀ alkyl group, a C₂₋₁₀ alkenyl group, a C₆₋₄₀ aryl group, or any combination of these possibly containing an ether bond, a ketone bond, or an ester bond; R₃ is a hydrogen atom, a C₁₋₁₀ alkyl group, a C₂₋₁₀ alkenyl group, a C₂₋₁₀ alkynyl group, a C₆₋₄₀ aryl group, or any combination of these possibly containing an ether bond, a ketone bond, or an ester bond; and n₁ and n₂ are each an integer of 1 to 3 when Ar₁ and Ar₂ are each a benzene ring, or an integer of 1 to 5 when Ar₁ and Ar₂ are each a naphthalene ring; and

in Formula (3), X is a single bond, a saturated or unsaturated linear or cyclic organic group having a carbon atom number of 1 to 30 and possibly containing a nitrogen atom, an oxygen atom, or a sulfur atom, or a C₆₋₃₀ arylene group).

Two or more compounds of Formula (1) or (2) may be used. The compounds will next be described.

### Compound of Formula (1) or (2)

In Formula (1) or (2), Ar₁ and Ar₂ are each independently a benzene ring or naphthalene ring substitutable with R₁ or R₂; R₁ and R₂ are each a hydrogen atom, a halogen atom, a nitro group, an amino group, a hydroxyl group, a C₁₋₁₀ alkyl group, a C₂₋₁₀ alkenyl group, a C₆₋₄₀ aryl group, or any combination of these possibly containing an ether bond, a ketone bond, or an ester bond; R₃ is a hydrogen atom, a C₁₋₁₀ alkyl group, a C₂₋₁₀ alkenyl group, a C₂₋₁₀ alkynyl group, a C₆₋₄₀ aryl group, or any combination of these possibly containing an ether bond, a ketone bond, or an ester bond; and n₁ and n₂ are each an integer of 1 to 3 when Ar₁ and Ar₂ are each a benzene ring, or an integer of 1 to 5 when Ar₁ and Ar₂ are each a naphthalene ring.

Examples of the aforementioned halogen atom include fluorine atom, chlorine atom, bromine atom, and iodine atom.

Examples of the aforementioned C₁₋₁₀ alkyl group include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group.

Examples of the aforementioned C₂₋₁₀ alkenyl group include ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group.

Examples of the aforementioned C₆₋₄₀ aryl group include phenyl group, o-methylphenyl group, m-methylphenyl group, p-methylphenyl group, o-chlorophenyl group, m-chlorophenyl group, p-chlorophenyl group, o-fluorophenyl group, p-fluorophenyl group, o-methoxyphenyl group, p-methoxyphenyl group, p-nitrophenyl group, p-cyanophenyl group, a-naphthyl group, β-naphthyl group, o-biphenyl group, m-biphenyl group, p-biphenyl group, 1-anthryl group, 2-anthryl group, 9-anthryl group, 1-phenanthryl group, 2-phenanthryl group, 3-phenanthryl group, 4-phenanthryl group, and 9-phenanthryl group.

Examples of the C₂₋₁₀ alkynyl group include ethynyl group, 1-propynyl group, 1-butynyl group, 1-methyl-3-pentynyl group, 1-methyl-3-hexynyl group, and 2-methyl-3-hexynyl group.

Specific examples of the combination of the hydrogen atom, C₁₋₁₀ alkyl group, C₂₋₁₀ alkenyl group, C₂₋₁₀ alkynyl group, and C₆₋₄₀ aryl group of R₃ are the following groups.

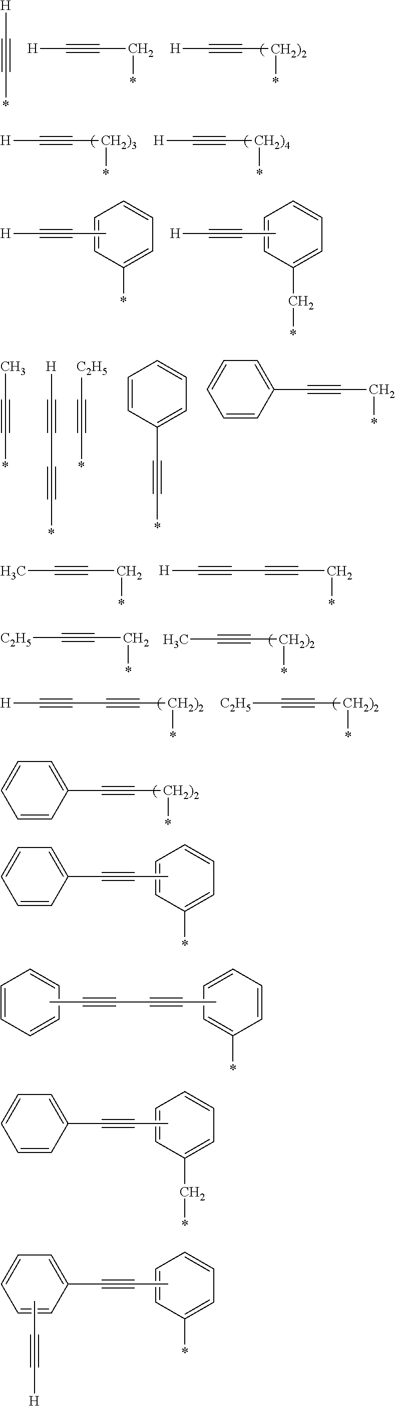

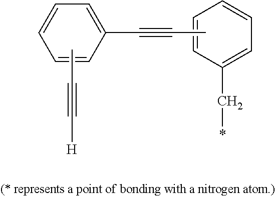

Examples of the carbazole compound of Formula (1) used in the present invention for polymer production include carbazole, N-methylcarbazole, N-ethylcarbazole, 1,3,6,8-tetranitrocarbazole, 3,6-diaminocarbazole, 3,6-dibromo-9-ethylcarbazole, 3,6-dibromo-9-phenylcarbazole, 3,6-dibromocarbazole, 3,6-dichlorocarbazole, 3-amino-9-ethylcarbazole, 3-bromo-9-ethylcarbazole, 4,4′-bis(9H-carbazol-9-yl)biphenyl, 9-ethylcarbazole, 4-glycidylcarbazole, 4-hydroxycarbazole, 9-(1H-benzotriazol-1-ylmethyl)-9H-carbazole, 9-acetyl-3,6-diiodocarbazole, 9-benzoylcarbazole, 9-benzoylcarbazole-6-dicarboxaldehyde, 9-benzylcarbazole-3-carboxaldehyde, 9-methylcarbazole, 9-phenylcarbazole, 9-vinylcarbazole, carbazole potassium, carbazole-N-carbonyl chloride, N-ethylcarbazole-3-carboxaldehyde, and N-((9-ethylcarbazol-3-yl)methylene)-2-methyl-1-indolinylamine. These compounds may be used alone or in combination of two or more species.

### Compound of Formula (3)

OHC—X—CHO Formula (3)

(In Formula (3), X is a single bond, a saturated or unsaturated linear or cyclic organic group having a carbon atom number of 1 to 30 and possibly containing a nitrogen atom, an oxygen atom, or a sulfur atom, or a C₆₋₃₀ arylene group.)

Examples of the dialdehyde compound of Formula (3) are compounds of the following Formulae.

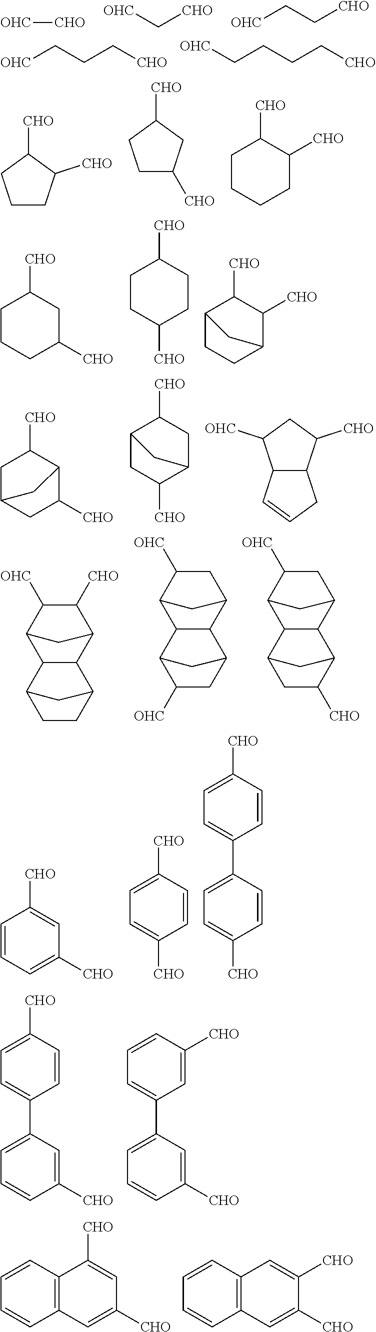

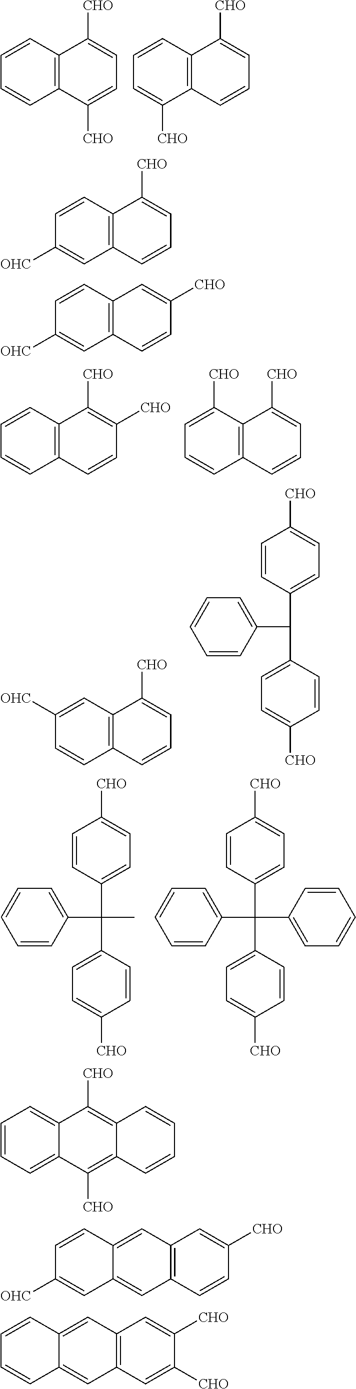

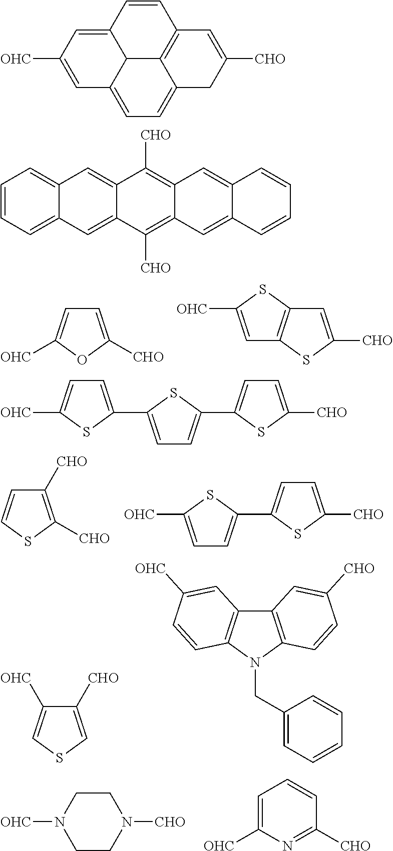

The dialdehyde compound of Formula (3) is preferably a dialdehyde compound wherein X is a single bond or a saturated or unsaturated linear or cyclic organic group having a carbon atom number of 1 to 30 and possibly containing a nitrogen atom, particularly preferably a dialdehyde compound wherein X is a single bond.

Since such a dialdehyde compound is readily available, the production cost of the resultant resist underlayer film composition can be reduced.

An equivalent of the above-exemplified dialdehyde compound may also be used. For example, the equivalent of the compound of Formula (3) may be a compound of the following Formula:

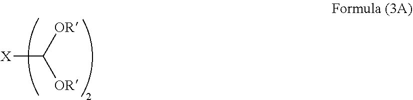

(wherein X has the same meaning as defined above, and R's are each a monovalent C₁₋₁₀ hydrocarbon group and may be identical to or different from each other);

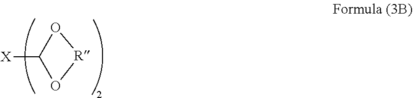

(wherein X has the same meaning as defined above, and R″ is a divalent C₁₋₁₀ hydrocarbon group); or

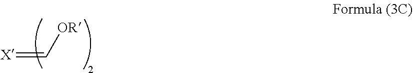

(wherein X′ is an organic group prepared by removal of one hydrogen atom from the aforementioned group of X, and R′ is a monovalent C₁₋₁₀ hydrocarbon group) when a hydrogen atom is bonded to the α-carbon atom of a formyl group.

Specific examples of the equivalent of Formula (3A) are as follows.

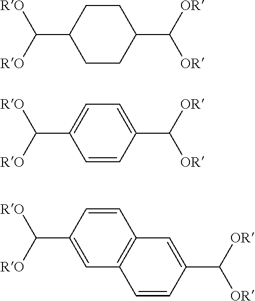

Other similar dialdehyde compounds may also be used.

Specific examples of the equivalent of Formula (3B) are as follows.

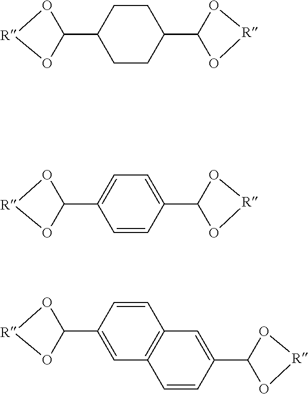

Other similar dialdehyde compounds may also be used.

Specific examples of the equivalent of Formula (3C) are as follows.

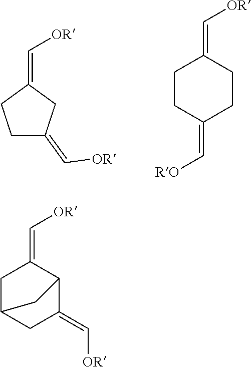

Other similar dialdehyde compounds may also be used.

Regarding the ratio of the dialdehyde compound of Formula (3) to the compound of Formula (1) or (2), the amount of the dialdehyde compound of Formula (3) is preferably 0.01 to 5 mol, more preferably 0.1 to 2 mol, relative to 1 mol of the compound of Formula (1) or (2).

The resist underlayer film material of the present invention may contain a polymer prepared by condensation of one compound or two or more compounds of Formula (1) or (2) and one or more compounds of Formula (3) and/or an equivalent thereof.

### Additional Aromatic Compound

So long as the effects of the present invention are not impaired, the resist underlayer film material of the present invention may contain, as a third component, an additional aromatic compound other than the compound of Formula (1) or (2), and the aromatic compound may be condensed with the compound of Formula (3).

Examples of the aromatic compound include phenol compounds, naphthol compounds, bisphenol compounds, and polyphenol compounds.

### Reaction Product

The reaction product is a polymer prepared by condensation of the compound of Formula (1) or (2), the additional aromatic compound (if necessary), and the compound of Formula (3). As described above, the present invention may involve the use of one compound or two or more compounds of Formula (1) or (2), and one additional aromatic compound or two or more additional aromatic compounds. Thus, the aforementioned polymer may be a multi-component copolymer.

A monomer other than the compound of Formula (1) or (2) and the compound of Formula (3) may be used for copolymerization in such an amount that the effects of the present invention are not impaired (e.g., less than 50% by mole, less than 30% by mole, less than 20% by mole, less than 10% by mole, or less than 5% by mole).

Examples of the acid catalyst used for the reaction include mineral acids such as sulfuric acid, phosphoric acid, and perchloric acid; organic sulfonic acids such as p-toluenesulfonic acid, p-toluenesulfonic acid monohydrate, and methanesulfonic acid; and carboxylic acids such as formic acid and oxalic acid. The amount of the acid catalyst used is appropriately determined depending on the type of the acid used. The amount of the acid catalyst used is generally 0.001 to 10,000 parts by mass, preferably 0.01 to 1,000 parts by mass, more preferably 0.1 to 100 parts by mass, relative to 100 parts by mass of the compound of Formula (1) or (2).

The aforementioned condensation reaction and addition reaction may be performed without use of a solvent, but generally performed with use of a solvent. Any solvent may be used, so long as it does not inhibit the reaction. Examples of the solvent include ethers, such as 1,2-dimethoxyethane, diethylene glycol dimethyl ether, propylene glycol monomethyl ether, propylene glycol monomethyl ether acetate, tetrahydrofuran, and dioxane.

If necessary, a polymerization inhibitor (radical trapping agent) may be added during the reaction. Specific examples of the polymerization initiator include 2,6-diisobutylphenol, 3,5-di-tert-butylphenol, 3,5-di-tert-butylcresol, hydroquinone, hydroquinone monomethyl ether, pyrogallol, tert-butylcatechol, and 4-methoxy-1-naphthol. In the case of addition of a polymerization inhibitor, the amount of the polymerization inhibitor added is preferably 1% by mass or less relative to the total solid content.

The reaction temperature is generally 40° C. to 200° C. The reaction time is appropriately determined depending on the reaction temperature, and is generally about 30 minutes to 50 hours.

The polymer prepared as described above has a weight average molecular weight Mw of generally 500 to 1,000,000 or 600 to 500,000.

The reaction product suitably used in the present invention will be described in Examples hereinbelow.

### Solvent

No particular limitation is imposed on the solvent used in the resist underlayer film-forming composition of the present invention, so long as the solvent can dissolve the aforementioned reaction product. In particular, the resist underlayer film-forming composition of the present invention is used in the form of homogeneous solution. Thus, in consideration of the coating performance of the composition, the solvent is recommended to be used in combination with a solvent commonly used in a lithographic process.

Examples of such a solvent include methylcellosolve acetate, ethylcellosolve acetate, propylene glycol, propylene glycol monomethyl ether, propylene glycol monoethyl ether, methyl isobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropinoate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol mooethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, N,N-dimethylformamide, N-methylacetamide, N,N-dimethylacetamide, N-methylpyrrolidone, 4-methyl-2-pentanol, and γ-butyrolactone. These solvents may be used alone or in combination of two or more species.

The following compound described in WO2018/131562A1 may also be used:

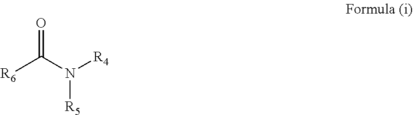

(in Formula (i), R₄, R₅, and R₆ are each a hydrogen atom or a C₁₋₂₀ alkyl group that may be interrupted by an oxygen atom, a sulfur atom, or an amide bond, may be identical to or different from one another, and may be bonded together to form a ring structure).

The C₁₋₂₀ alkyl group is, for example, a linear or branched alkyl group that may have or may not have a substituent. Examples of the alkyl group include methyl group, ethyl group, n-propyl group, isopropyl group, n-butyl group, sec-butyl group, tert-butyl group, n-pentyl group, isopentyl group, neopentyl group, n-hexyl group, isohexyl group, n-heptyl group, n-octyl group, cyclohexyl group, 2-ethylhexyl group, n-nonyl group, isononyl group, p-tert-butylcyclohexyl group, n-decyl group, n-dodecylnonyl group, undecyl group, dodecyl group, tridecyl group, tetradecyl group, pentadecyl group, hexadecyl group, heptadecyl group, octadecyl group, nonadecyl group, and eicosyl group. Preferred is a C₁₋₁₂ alkyl group, more preferred is a C₁₋₈ alkyl group, and still more preferred is a C₁₋₄ alkyl group.

The C₁₋₂₀ alkyl group interrupted by an oxygen atom, a sulfur atom, or an amide bond is, for example, one containing a structural unit —CH₂—O—, —CH₂—S—, —CH₂—NHCO—, or —CH₂—CONH—. The alkyl group may contain one unit or two or more units of —O—, —S—, —NHCO—, or —CONH—. Specific examples of the C₁₋₂₀ alkyl group interrupted by the —O—, —S—, —NHCO—, or —CONH— unit include methoxy group, ethoxy group, propoxy group, butoxy group, methylthio group, ethylthio group, propylthio group, butylthio group, methylcarbonylamino group, ethylcarbonylamino group, propylcarbonylamino group, butylcarbonylamino group, methylaminocarbonyl group, ethylaminocarbonyl group, propylaminocarbonyl group, and butylaminocarbonyl group. Other examples include methyl group, ethyl group, propyl group, butyl group, pentyl group, hexyl group, heptyl group, octyl group, nonyl group, decyl group, dodecyl group, or octadecyl group, wherein each of these groups is substituted with, for example, methoxy group, ethoxy group, propoxy group, butoxy group, methylthio group, ethylthio group, propylthio group, butylthio group, methylcarbonylamino group, ethylcarbonylamino group, methylaminocarbonyl group, or ethylaminocarbonyl group. Preferred is a methoxy group, an ethoxy group, a methylthio group, or an ethylthio group, and more preferred is a methoxy group or an ethoxy group.

Since any of these solvents has a relatively high boiling point, the solvent is effective for providing the resist underlayer film-forming composition with a high embedding property and a high flattening property.

Specific examples of preferred compounds of Formula (i) are as follows.

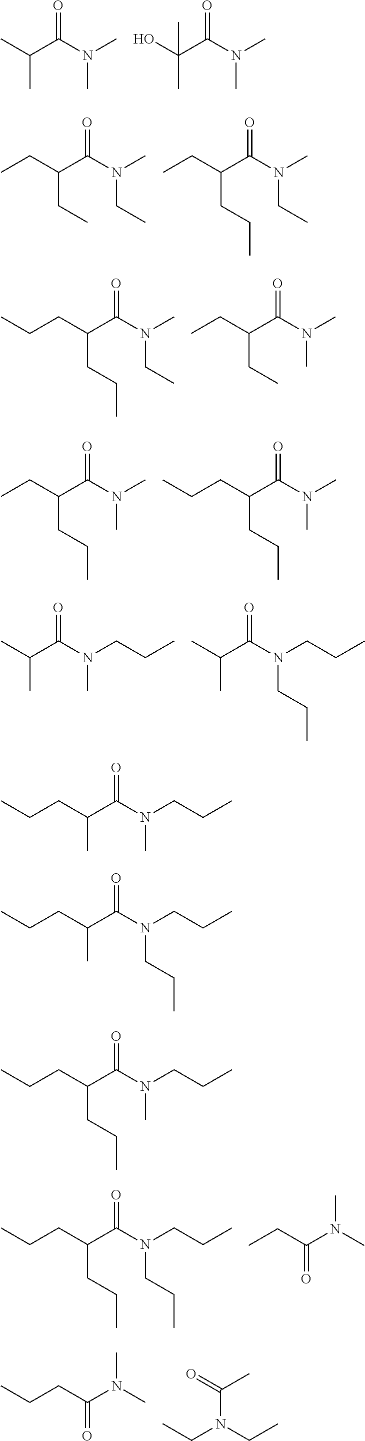

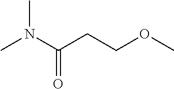

Among the aforementioned compounds, preferred are 3-methoxy-N,N-dimethylpropionamide, N,N-dimethylisobutylamide, and compounds of the following formula:

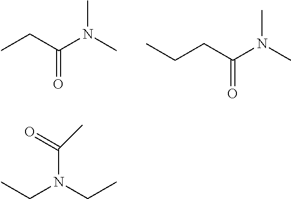

and particularly preferred compounds of Formula (i) are 3-methoxy-N,N-dimethylpropionamide and N,N-dimethylisobutylamide.

These solvents may be used alone or in combination of two or more species. Among these solvents, preferred are solvents having a boiling point of 160° C. or higher, for example, propylene glycol monomethyl ether, propylene glycol monomethyl ether acetate, ethyl lactate, butyl lactate, cyclohexanone, 3-methoxy-N,N-dimethylpropionamide, N,N-dimethylisobutylamide, 2,5-dimethylhexane-1,6-diyl diacetate (DAH; cas, 89182-68-3), and 1,6-diacetoxyhexane (cas, 6222-17-9). Particularly preferred are propylene glycol monomethyl ether, propylene glycol monomethyl ether acetate, and N,N-dimethylisobutylamide.

### Crosslinking Agent Component

The resist underlayer film-forming composition of the present invention may contain a crosslinking agent component. The crosslinking agent is, for example, a melamine compound, a substituted urea compound, or a polymer thereof. The crosslinking agent is preferably a crosslinking agent having at least two crosslinkable substituents, for example, a compound such as methoxymethylated glycoluril (e.g., tetramethoxymethyl glycoluril), butoxymethylated glycoluril, methoxymethylated melamine, butoxymethylated melamine, methoxymethylated benzoguanamine, butoxymethylated benzoguanamine, methoxymethylated urea, butoxymethylated urea, or methoxymethylated thiourea. A condensate of such a compound may also be used.

The aforementioned crosslinking agent may be a crosslinking agent having a high thermal resistance. The crosslinking agent having a high thermal resistance is preferably a compound containing a crosslinkable substituent having an aromatic ring (e.g., a benzene ring or a naphthalene ring) in the molecule.

Examples of the compound include a compound having a partial structure of the following Formula (4) and a polymer or oligomer having a repeating unit of the following Formula (5).

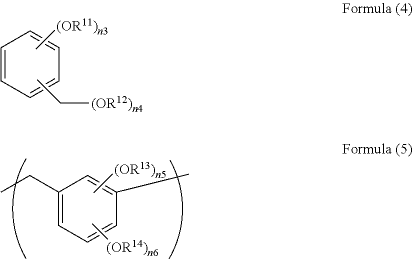

In the aforementioned formulae, R¹¹, R¹², R¹³, and and R¹⁴ are each a hydrogen atom or a C₁₋₁₀ alkyl group, and these alkyl groups may be those exemplified above. In the aforementioned formulae, n3 is an integer of 1 to 4, n4 is an integer of 1 to (5−n3), (n3+n4) is an integer of 2 to 5, n5 is an integer of 1 to 4, n6 is 0 to (4−n5), and (n5+n6) is an integer of 1 to 4. Each of the oligomer and the polymer may have 2 to 100 or 2 to 50 repeating unit structures.

Examples of the compound of Formula (4) and the polymer or oligomer of Formula (5) are as follows.

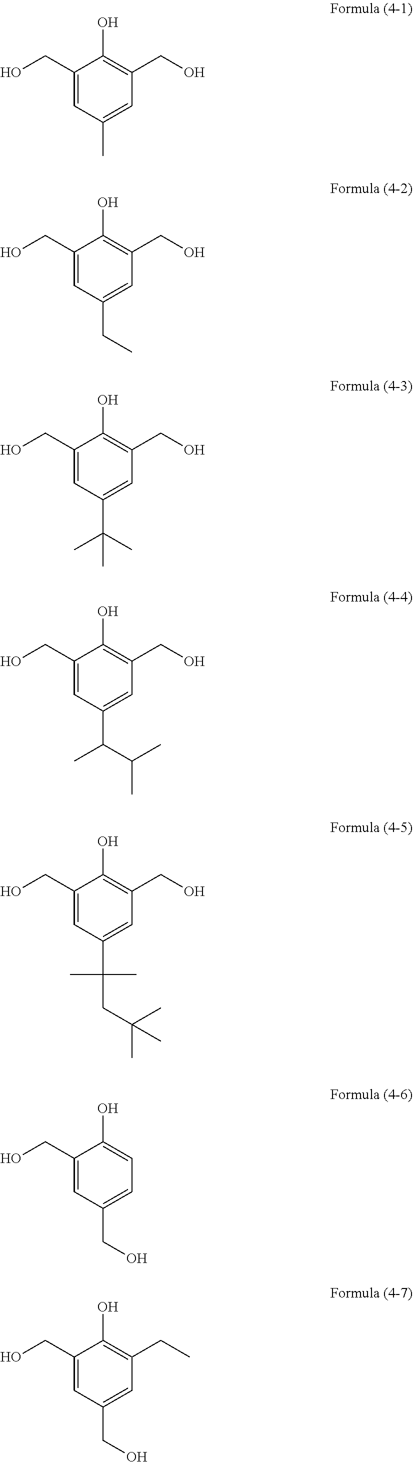

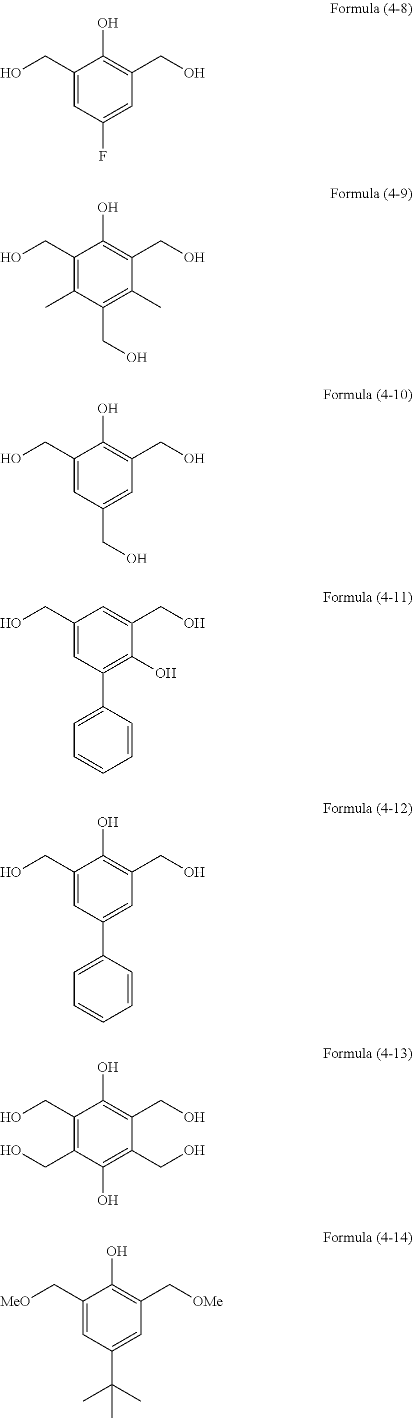

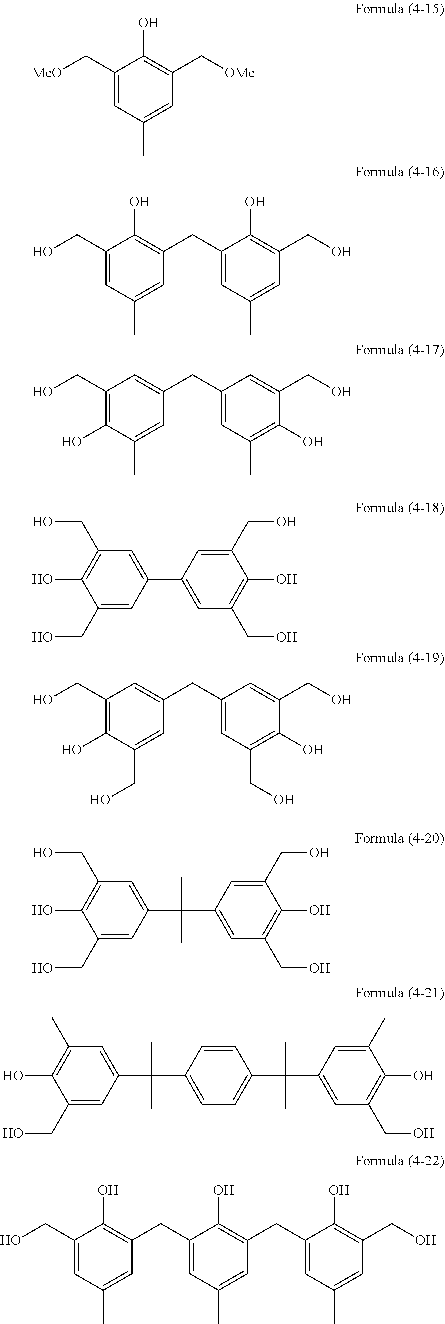

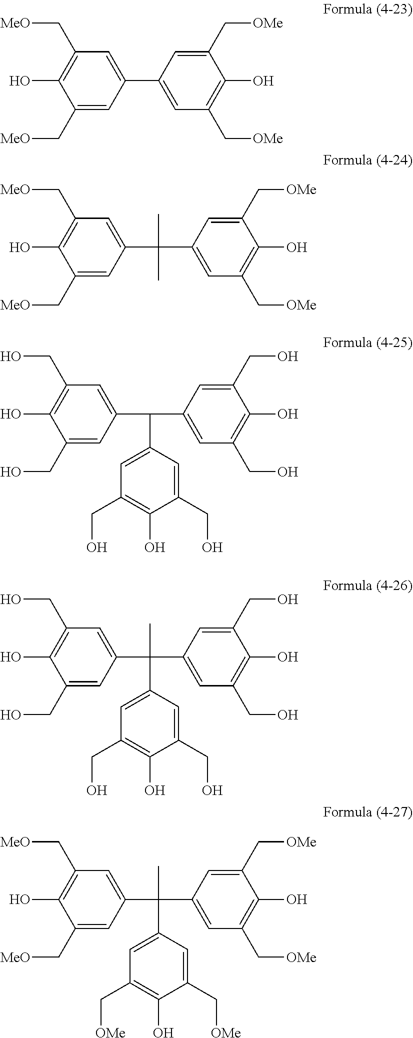 [SMILES: COCc1cc(-c2cc(COC)c(O)c(COC)c2)cc(COC)c1O ; COCc1cc(C(C)(C)c2cc(COC)c(O)c(COC)c2)cc(COC)c1O ; OCc1cc(C(c2cc(CO)c(O)c(CO)c2)c2cc(CO)c(O)c(CO)c2)cc(CO)c1O ; CC(c1cc(CO)c(O)c(CO)c1)(c1cc(CO)c(O)c(CO)c1)c1cc(CO)c(O)c(CO)c1 ; COCc1cc(C(C)(c2cc(COC)c(O)c(COC)c2)c2cc(COC)c(O)c(COC)c2)cc(COC)c1O]

The aforementioned compounds can be obtained as products available from ASAHI YUKIZAI CORPORATION and Honshu Chemical Industry Co., Ltd. For example, among the aforementioned crosslinking agents, the compound of Formula (4-24) can be obtained as trade name TM-BIP-A available from ASAHI YUKIZAI CORPORATION.

The amount of the crosslinking agent added may vary depending on, for example, the type of a coating solvent used, the type of an underlying substrate used, the viscosity of a solution required, or the shape of a film required. The amount of the crosslinking agent is 0.001 to 80% by mass, preferably 0.01 to 50% by mass, more preferably 0.05 to 40% by mass, relative to the total solid content. Such a crosslinking agent may cause a crosslinking reaction by its self-condensation. When a crosslinkable substituent is present in the aforementioned reaction product of the present invention, such a crosslinking agent may cause a crosslinking reaction with the crosslinkable substituent.

### Acid and/or Acid Generator

The resist underlayer film-forming composition of the present invention may contain an acid and/or an acid generator.

Examples of the acid include p-toluenesulfonic acid, trifluoromethanesulfonic acid, pyridinium p-toluenesulfonic acid, pyridinium phenolsulfonic acid, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, citric acid, benzoic acid, hydroxybenzoic acid, and naphthalenecarboxylic acid.

A single acid may be used alone, or two or more acids may be used in combination. The amount of the acid is generally 0.0001 to 20% by mass, preferably 0.0005 to 10% by mass, more preferably 0.01 to 3% by mass, relative to the total solid content.

The acid generator may be, for example, a thermal acid generator or a photoacid generator.

Examples of the thermal acid generator include

2,4,4,6-tetrabromocyclohexadienone, benzoin tosylate, 2-nitrobenzyl tosylate, K-PURE [registered trademark] CXC-1612, CXC-1614, TAG-2172, TAG-2179, TAG-2678, TAG2689, and TAG2700 (available from King Industries Inc.), SI-45, SI-60, SI-80, SI-100, SI-110, and SI-150 (available from SANSHIN CHEMICAL INDUSTRY CO., LTD.), and other organic sulfonic acid alkyl esters.

A photoacid generator generates an acid during the exposure of a resist. Thus, the acidity of an underlayer film can be adjusted. This is one method for adjusting the acidity of an underlayer film to the acidity of a resist serving as an upper layer of the underlayer film. Furthermore, the adjustment of the acidity of an underlayer film enables the control of the pattern shape of a resist formed as an upper layer of the underlayer film.

Examples of the photoacid generator contained in the resist underlayer film-forming composition of the present invention include an onium salt compound, a sulfonimide compound, and a disulfonyldiazomethane compound.

Examples of the onium salt compound include iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, and triphenylsulfonium trifluoromethanesulfonate.

Examples of the sulfonimide compound include N-(trifluoromethanesulfonyloxy)succinimide, N-(nonafluoro normal butane sulfonyloxy)succinimide, N-(camphorsulfonyloxy)succinimide, and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

A single acid generator may be used alone, or two or more acid generators may be used in combination.

When an acid generator is used, the amount thereof is 0.01 to 5 parts by mass, or 0.1 to 3 parts by mass, or 0.5 to 1 part by mass, relative to 100 parts by mass of the solid content of the resist underlayer film-forming composition.

### Additional Component

The resist underlayer film-forming composition of the present invention may contain a surfactant for further improving the applicability of the composition to an uneven surface without causing, for example, pinholes or striations. Examples of the surfactant include nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylallyl ethers, such as polyoxyethylene octylphenol ether and polyoxyethylene nonylphenol ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-containing surfactants, such as EFTOP EF301, EF303, and EF352 (trade name, available from Tohkem Products Corporation), MEGAFACE F171, F173, R-40, R-40N, and R-40LM (trade name, available from DIC Corporation), Fluorad FC430 and FC431 (trade name, available from Sumitomo 3M Limited), Asahi Guard AG710 and SURFLON S-382, SC101, SC102, SC103, SC104, SC105, and SC106 (trade name, available from Asahi Glass Co., Ltd.); and Organosiloxane Polymer KP341 (available from Shin-Etsu Chemical Co., Ltd.). The amount of such a surfactant is generally 2.0% by mass or less, preferably 1.0% by mass or less, relative to the total solid content of the resist underlayer film material. These surfactants may be used alone or in combination of two or more species. When a surfactant is used, the amount thereof is 0.0001 to 5 parts by mass, or 0.001 to 1 part by mass, or 0.01 to 0.5 parts by mass, relative to 100 parts by mass of the solid content of the resist underlayer film-forming composition.

The resist underlayer film-forming composition of the present invention may contain a light-absorbing agent, a rheology controlling agent, an adhesion aid, etc.

The rheology controlling agent is effective for improving the fluidity of the underlayer film-forming composition. The adhesion aid is effective for improving the adhesion between a semiconductor substrate or a resist and an underlayer film.

Preferred examples of the light-absorbing agent include commercially available light-absorbing agents described in “Kogyoyo Shikiso no Gijutsu to Shijo (Technology and Market of Industrial Colorant)” (CMC Publishing Co., Ltd.) and “Senryo Binran (Dye Book)” (edited by The Society of Synthetic Organic Chemistry, Japan), such as C. I. Disperse Yellow 1, 3, 4, 5, 7, 8, 13, 23, 31, 49, 50, 51, 54, 60, 64, 66, 68, 79, 82, 88, 90, 93, 102, 114, and 124; C. I. Disperse Orange 1, 5, 13, 25, 29, 30, 31, 44, 57, 72, and 73; C. I. Disperse Red 1, 5, 7, 13, 17, 19, 43, 50, 54, 58, 65, 72, 73, 88, 117, 137, 143, 199, and 210; C. I. Disperse Violet 43; C. I. Disperse Blue 96; C. I. Fluorescent Brightening Agent 112, 135, and 163; C. I. Solvent Orange 2 and 45; C. I. Solvent Red 1, 3, 8, 23, 24, 25, 27, and 49; C. I. Pigment Green 10; and C. I. Pigment Brown 2. The light-absorbing agent is incorporated in an amount of generally 10% by mass or less, preferably 5% by mass or less, relative to the total solid content of the resist underlayer film-forming composition.

The rheology controlling agent is incorporated for the main purpose of improving the fluidity of the resist underlayer film-forming composition; in particular, the purpose of improving the thickness uniformity of a resist underlayer film or improving filling of the interior of a hole with the resist underlayer film-forming composition in a baking process. Specific examples of the rheology controlling agent include phthalic acid derivatives, such as dimethyl phthalate, diethyl phthalate, diisobutyl phthalate, dihexyl phthalate, and butyl isodecyl phthalate; adipic acid derivatives, such as di-normal butyl adipate, diisobutyl adipate, diisooctyl adipate, and octyldecyl adipate; maleic acid derivatives, such as di-normal butyl maleate, diethyl maleate, and dinonyl maleate; oleic acid derivatives, such as methyl oleate, butyl oleate, and tetrahydrofurfuryl oleate; and stearic acid derivatives, such as normal butyl stearate and glyceryl stearate. Such a rheology controlling agent is incorporated in an amount of generally less than 30% by mass relative to the total solid content of the resist underlayer film-forming composition.

The adhesion aid is incorporated for the main purpose of improving the adhesion between a substrate or a resist and the resist underlayer film-forming composition; in particular, the purpose of preventing peeling of the resist during development. Specific examples of the adhesion aid include chlorosilane compounds, such as trimethylchlorosilane, dimethylmethylolchlorosilane, methyldiphenylchlorosilane, and chloromethyldimethylchlorosilane; alkoxysilane compounds, such as trimethylmethoxysilane, dimethyldiethoxysilane, methyldimethoxysilane, dimethylmethylolethoxysilane, diphenyldimethoxysilane, and phenyltriethoxysilane; silazane compounds, such as hexamethyldisilazane, N,N′-bis(trimethylsilyl)urea, dimethyltrimethylsilylamine, and trimethylsilylimidazole; silane compounds, such as methyloltrichlorosilane, γ-chloropropyltrimethoxysilane, γ-aminopropyltriethoxysilane, and γ-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; and urea or thiourea compounds, such as 1,1-dimethylurea and 1,3-dimethylurea. Such an adhesion aid is incorporated in an amount of generally less than 5% by mass, preferably less than 2% by mass, relative to the total solid content of the resist underlayer film-forming composition.

The resist underlayer film-forming composition of the present invention has a solid content of generally 0.1 to 70% by mass, preferably 0.1 to 60% by mass. The term “solid content” as used herein refers to the amount of all components (except for the solvent) contained in the resist underlayer film-forming composition. The amount of the aforementioned reaction product in the solid content is 1 to 100% by mass, 1 to 99.9% by mass, 50 to 99.9% by mass, 50 to 95% by mass, or 50 to 90% by mass (preferably in this order).

One measure for evaluating whether the resist underlayer film-forming composition is in the form of homogeneous solution is to observe the permeation of the composition through a specific microfilter. The resist underlayer film-forming composition of the present invention permeates through a microfilter having a pore size of 0.1 μm, and thus is in the form of homogeneous solution.

Examples of the material of the aforementioned microfilter include fluororesins such as PTFE (polytetrafluoroethylene) and PFA (tetrafluoroethylene-perfluoroalkyl vinyl ether copolymer), PE (polyethylene), UPE (ultra-high molecular weight polyethylene), PP (polypropylene), PSF (polysulfone), PES (polyethersulfone), and nylon. Preferably, the microfilter is formed of PTFE (polytetrafluoroethylene).

### Methods of Producing Resist Underlayer Film and Semiconductor Device

Next will be described methods of producing a resist underlayer film and a semiconductor device using the resist underlayer film-forming composition of the present invention.

The resist underlayer film-forming composition of the present invention is applied onto a substrate used for the production of a semiconductor device (e.g., a silicon wafer substrate, a silicon/silicon dioxide-coated substrate, a silicon nitride substrate, a glass substrate, an ITO substrate, a polyimide substrate, or a substrate coated with a low dielectric constant material (low-k material)) by an appropriate application method with, for example, a spinner or a coater, followed by baking of the composition, to thereby form a resist underlayer film. The baking is performed under appropriately determined conditions; i.e., a baking temperature of 80° C. to 400° C. and a baking time of 0.3 to 60 minutes. Preferably, the baking temperature is 150° C. to 350° C., and the baking time is 0.5 to 2 minutes. The thickness of the thus-formed underlayer film is, for example, 10 to 1,000 nm, or 20 to 500 nm, or 30 to 400 nm, or 50 to 300 nm.

An inorganic resist underlayer film (hard mask) may be formed on the organic resist underlayer film of the present invention. For example, an inorganic resist underlayer film may be formed by spin coating of the silicon-containing resist underlayer film (inorganic resist underlayer film)-forming composition described in WO 2009/104552A1, or an Si-containing inorganic material film may be formed by the CVD method, etc.

The resist underlayer film-forming composition of the present invention may be applied onto a semiconductor substrate having a stepped portion and a non-stepped portion (i.e., an uneven substrate), followed by baking of the composition, to thereby form a resist underlayer film wherein a difference in level between the stepped portion and the non-stepped portion falls within a range of 3 to 70 nm.

Subsequently, a resist film (e.g., a photoresist layer) is formed on the resist underlayer film. The photoresist layer may be formed by a well-known process; i.e., application of a photoresist composition solution onto the underlayer film, and subsequent baking. The thickness of the photoresist layer is, for example, 50 to 10,000 nm, or 100 to 2,000 nm, or 200 to 1,000 nm.

No particular limitation is imposed on the photoresist formed on the resist underlayer film, so long as the photoresist is sensitive to light used for exposure. The photoresist may be either of negative and positive photoresists. Examples of the photoresist include a positive photoresist formed of a novolac resin and a 1,2-naphthoquinone diazide sulfonic acid ester; a chemically amplified photoresist formed of a binder having a group that decomposes with an acid to thereby increase the alkali dissolution rate and a photoacid generator; a chemically amplified photoresist formed of a low-molecular-weight compound that decomposes with an acid to thereby increase the alkali dissolution rate of the photoresist, an alkali-soluble binder, and a photoacid generator; and a chemically amplified photoresist formed of a binder having a group that decomposes with an acid to thereby increase the alkali dissolution rate, a low-molecular-weight compound that decomposes with an acid to thereby increase the alkali dissolution rate of the photoresist, and a photoacid generator. Specific examples of the photoresist include trade name APEX-E, available from Shipley, trade name PAR710, available from Sumitomo Chemical Company, Limited, and trade name SEPR430, available from Shin-Etsu Chemical Co., Ltd. Other examples of the photoresist include fluorine atom-containing polymer-based photoresists described in Proc. SPIE, Vol. 3999, 330-334 (2000), Proc. SPIE, Vol. 3999, 357-364 (2000), and Proc. SPIE, Vol. 3999, 365-374 (2000).

Subsequently, a resist pattern is formed by irradiation with light or electron beams and development. Firstly, light exposure is performed through a predetermined mask. The light exposure is performed with, such as near-ultraviolet rays, far-ultraviolet rays, or extreme-ultraviolet rays (e.g., EUV, wavelength: 13.5 nm). Specifically, the light exposure may involve the use of, for example, a KrF excimer laser (wavelength: 248 nm), an ArF excimer laser (wavelength: 193 nm), and an F₂ excimer laser (wavelength: 157 nm). Of these, an ArF excimer laser (wavelength: 193 nm) and EUV (wavelength: 13.5 nm) are preferred. After the light exposure, post exposure bake may be performed as appropriate. The post exposure bake is performed under appropriately determined conditions; i.e., a heating temperature of 70° C. to 150° C. and a heating time of 0.3 to 10 minutes.

In the present invention, a resist for electron beam lithography may be used in place of the photoresist. The electron beam resist may be either of negative and positive resists. Examples of the electron beam resist include a chemically amplified resist formed of an acid generator and a binder having a group that decomposes with an acid to thereby change the alkali dissolution rate; a chemically amplified resist formed of an alkali-soluble binder, an acid generator, and a low-molecular-weight compound that decomposes with an acid to thereby change the alkali dissolution rate of the resist; a chemically amplified resist formed of an acid generator, a binder having a group that decomposes with an acid to thereby change the alkali dissolution rate, and a low-molecular-weight compound that decomposes with an acid to thereby change the alkali dissolution rate of the resist; a non-chemically amplified resist formed of a binder having a group that decomposes with electron beams to thereby change the alkali dissolution rate; and a non-chemically amplified resist formed of a binder having a moiety that is cut with electron beams to thereby change the alkali dissolution rate. Also, in the case of use of such an electron beam resist, a resist pattern can be formed by using electron beams as an irradiation source in the same manner as in the case of using the photoresist.

Subsequently, development is performed with a developer. When, for example, a positive photoresist is used, an exposed portion of the photoresist is removed to thereby form a pattern of the photoresist.

Examples of the developer include alkaline aqueous solutions, for example, aqueous solutions of alkali metal hydroxides, such as potassium hydroxide and sodium hydroxide; aqueous solutions of quaternary ammonium hydroxides, such as tetramethylammonium hydroxide, tetraethylammonium hydroxide, and choline; and aqueous solutions of amines, such as ethanolamine, propylamine, and ethylenediamine. Such a developer may also contain, for example, a surfactant. The development is performed under appropriately determined conditions; i.e., a temperature of 5° C. to 50° C. and a time of 10 to 600 seconds.

The resultant patterned photoresist (upper layer) is used as a protective film for removing the inorganic underlayer film (intermediate layer). Subsequently, the patterned photoresist and the patterned inorganic underlayer film (intermediate layer) are used as protective films for removing the organic underlayer film (lower layer). Finally, the patterned inorganic underlayer film (intermediate layer) and the patterned organic underlayer film (lower layer) are used as protective films for processing the semiconductor substrate.

Specifically, a photoresist-removed portion of the inorganic underlayer film (intermediate layer) is removed by dry etching to thereby expose the semiconductor substrate. The dry etching of the inorganic underlayer film can be performed with any of gasses, such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane. The dry etching of the inorganic underlayer film is preferably performed with a halogen-containing gas, more preferably with a fluorine-containing gas. Examples of the fluorine-containing gas include tetrafluoromethane (CF₄), perfluorocyclobutane (C₄F₈), perfluoropropane (C₃F₈), trifluoromethane, and difluoromethane (CH₂F₂).

Thereafter, the patterned photoresist and the patterned inorganic underlayer film are used as protective films for removing the organic underlayer film. The dry etching of the organic underlayer film (lower layer) is preferably performed with an oxygen-containing gas, since the inorganic underlayer film, which contains numerous silicon atoms, is less likely to be removed by dry etching with an oxygen-containing gas.

Finally, the semiconductor substrate is processed. The processing of the semiconductor substrate is preferably performed by dry etching with a fluorine-containing gas.

Examples of the fluorine-containing gas include tetrafluoromethane (CF₄), perfluorocyclobutane (C₄F₈), perfluoropropane (C₃F₈), trifluoromethane, and difluoromethane (CH₂F₂).

An organic anti-reflective coating may be formed on the resist underlayer film before formation of the photoresist. No particular limitation is imposed on the composition used for formation of the anti-reflective coating, and the composition may be appropriately selected from anti-reflective coating compositions that have been conventionally used in a lithographic process. The anti-reflective coating can be formed by a commonly used method, for example, application of the composition with a spinner or a coater, and baking of the composition.

In the present invention, the organic underlayer film can be formed on the substrate, the inorganic underlayer film can then be formed on the organic underlayer film, and then the inorganic underlayer film can be coated with a photoresist. This process can narrow the pattern width of the photoresist. Thus, even when the photoresist is applied thinly for preventing a pattern collapse, the substrate can be processed through selection of an appropriate etching gas. For example, the resist underlayer film can be processed by using, as an etching gas, a fluorine-containing gas that achieves a significantly high etching rate for the photoresist. The substrate can be processed by using, as an etching gas, a fluorine-containing gas that achieves a significantly high etching rate for the inorganic underlayer film. The substrate can be processed by using, as an etching gas, an oxygen-containing gas that achieves a significantly high etching rate for the organic underlayer film.

The resist underlayer film formed from the resist underlayer film-forming composition may absorb light used in a lithographic process depending on the wavelength of the light. In such a case, the resist underlayer film can function as an anti-reflective coating having the effect of preventing reflection of light from the substrate. Furthermore, the underlayer film formed from the resist underlayer film-forming composition of the present invention can function as a hard mask. The underlayer film of the present invention can be used as, for example, a layer for preventing the interaction between the substrate and the photoresist; a layer having the function of preventing the adverse effect, on the substrate, of a material used for the photoresist or a substance generated during the exposure of the photoresist to light; a layer having the function of preventing diffusion of a substance generated from the substrate during heating and baking to the photoresist serving as an upper layer; and a barrier layer for reducing a poisoning effect of a dielectric layer of the semiconductor substrate on the photoresist layer.

The underlayer film formed from the resist underlayer film-forming composition can be applied to a substrate having via holes for use in a dual damascene process, and can be used as an embedding material to fill up the holes. The underlayer film can also be used as a flattening material for flattening the surface of a semiconductor substrate having irregularities.

### EXAMPLES

The resist underlayer film-forming composition of the present invention will next be described in detail with reference to the following Examples, but the present invention should not be construed as being limited to the Examples.

The weight average molecular weight described in Synthesis Examples hereinbelow is measured by gel permeation chromatography (hereinafter abbreviated as “GPC”). The weight average molecular weight is measured with a GPC apparatus (HLC-8320GPC) available from TOSOH CORPORATION under the following conditions.
GPC column: TSKgel SuperH-RC, TSKgel SuperMultiporeHZ-N, TSKgel SuperMultiporeHZ-N (available from TOSOH CORPORATION)
Column temperature: 40° C.
Solvent: tetrahydrofuran (for high-performance liquid chromatography, available from Kanto Chemical Co., Inc.)
Standard sample: polystyrene (available from Shodex)

Abbreviations described in Synthesis Examples hereinbelow have the following meanings.
Cz: carbazole
ECz: 9-ethylcarbazole
Glyoxal: glyoxal
1Na: 1-naphthol
2,3-DMP: 2,3-dimethylphenol
Glutalaldehyde: glutaraldehyde
EHA: 2-ethylhexanal

### Synthesis Example 1

(Synthesis of Polymer (A))(Cz/Glyoxal=100/30)

A 200-mL four-necked flask equipped with a stirring bar and a cooling tube was charged with 20.00 g (119.61 mmol) of carbazole (available from Tokyo Chemical Industry Co., Ltd.), 5.34 g (35.88 mmol) of glyoxal (39% aqueous solution, about 8.8 mol/L, available from Tokyo Chemical Industry Co., Ltd.), 0.07 g (0.36 mmol) of p-toluenesulfonic acid monohydrate (available from Tokyo Chemical Industry Co., Ltd.), and 33.97 g of 1,4-dioxane (Cica special grade, available from Kanto Chemical Co., Inc.), and the resultant mixture was heated to 90° C. and stirred at 90° C. for 13 hours. After being cooled to 60° C. or lower, the mixture was diluted with 56.68 g of tetrahydrofuran (special grade, available from Kanto Chemical Co., Inc.), and the mixture was cooled to 30° C. or lower. The resultant reaction mixture was added dropwise to 1 L of a mixed solvent of methanol (special grade, available from Kanto Chemical Co., Inc.)/water (8/2), to thereby precipitate a polymer. The resultant precipitate was separated by filtration, and the residue was washed three times with 250 mL of methanol/water (8/2) and dried under vacuum, to thereby produce a polymer. The molecular weight of the polymer was measured by GPC (in terms of standard polystyrene). As a result, the polymer was found to have a weight average molecular weight (Mw) of 1,617 (yield: 38.1%). The polymer has a repeating unit structure of the following Formula (A). The resultant polymer was diluted with propylene glycol monomethyl ether acetate so as to achieve a solid content concentration of 30%. A cation-exchange resin and an anion-exchange resin were each added to the diluted polymer in an amount equal to the solid content, and the resultant mixture was stirred for four hours. The ion-exchange resins were filtered to thereby prepare a polymer (A) solution.

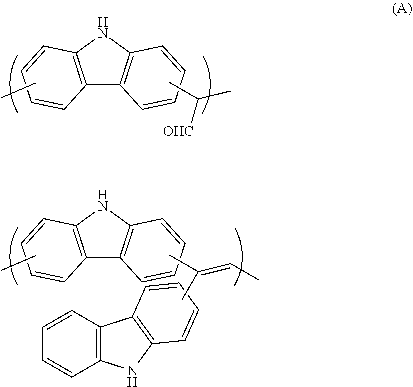

### Synthesis Example 2

(Synthesis of Polymer (B))(ECz/Glyoxal=100/70)

A 200-mL four-necked flask equipped with a stirring bar and a cooling tube was charged with 19.00 g (97.30 mmol) of 9-ethylcarbazole (available from Tokyo Chemical Industry Co., Ltd.), 10.14 g (68.11 mmol) of glyoxal (39% aqueous solution, about 8.8 mol/L, available from Tokyo Chemical Industry Co., Ltd.), 1.30 g (6.81 mmol) of p-toluenesulfonic acid monohydrate (available from Tokyo Chemical Industry Co., Ltd.), and 26.95 g of 1,4-dioxane (Cica special grade, available from Kanto Chemical Co., Inc.), and the resultant mixture was heated to 90° C. and stirred at 90° C. for 15 hours. After being cooled to 60° C. or lower, the mixture was diluted with 57.38 g of tetrahydrofuran (special grade, available from Kanto Chemical Co., Inc.), and the mixture was cooled to 30° C. or lower. The resultant reaction mixture was added dropwise to 1 L of 2-propanol (special grade, available from Kanto Chemical Co., Inc.), to thereby precipitate a polymer. The resultant precipitate was separated by filtration, and the residue was washed three times with 250 mL of 2-propanol and dried under vacuum, to thereby produce a polymer. The molecular weight of the polymer was measured by GPC (in terms of standard polystyrene). As a result, the polymer was found to have a weight average molecular weight (Mw) of 768 (yield: 44.8%). The polymer has a repeating unit structure of the following Formula (B). The resultant polymer was diluted with propylene glycol monomethyl ether acetate so as to achieve a solid content concentration of 30%. A cation-exchange resin and an anion-exchange resin were each added to the diluted polymer in an amount equal to the solid content, and the resultant mixture was stirred for four hours. The ion-exchange resins were filtered to thereby prepare a polymer (B) solution.

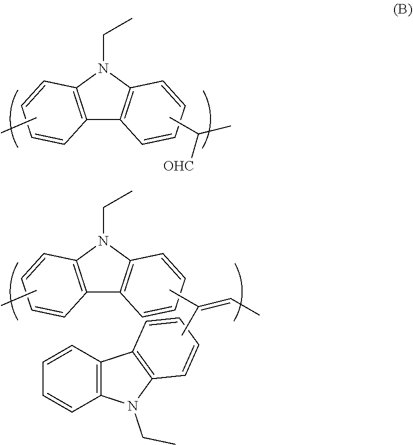

### Synthesis Example 3

(Synthesis of Polymer (C))(ECz/Cz/Glyoxal=70/30/70)

A 200-mL four-necked flask equipped with a stirring bar and a cooling tube was charged with 13.00 g (66.57 mmol) of 9-ethylcarbazole (available from Tokyo Chemical Industry Co., Ltd.), 4.77 g (28.53 mmol) of carbazole (available from Tokyo Chemical Industry Co., Ltd.), 9.91 g (66.57 mmol) of glyoxal (39% aqueous solution, about 8.8 mol/L, available from Tokyo Chemical Industry Co., Ltd.), 1.27 g (6.66 mmol) of p-toluenesulfonic acid monohydrate (available from Tokyo Chemical Industry Co., Ltd.), and 25.14 g of 1,4-dioxane (Cica special grade, available from Kanto Chemical Co., Inc.), and the resultant mixture was heated to 90° C. and stirred at 90° C. for 24 hours. After being cooled to 60° C. or lower, the mixture was diluted with 54.09 g of tetrahydrofuran (special grade, available from Kanto Chemical Co., Inc.), and the mixture was cooled to 30° C. or lower. The resultant reaction mixture was added dropwise to 1 L of a mixed solvent of methanol (special grade, available from Kanto Chemical Co., Inc.)/water (8/2), to thereby precipitate a polymer. The resultant precipitate was separated by filtration, and the residue was washed three times with 250 mL of methanol/water (8/2) and dried under vacuum, to thereby produce a polymer. The molecular weight of the polymer was measured by GPC (in terms of standard polystyrene). As a result, the polymer was found to have a weight average molecular weight (Mw) of 1,358 (yield: 75.7%). The polymer has a repeating unit structure of the following Formula (C). The resultant polymer was diluted with propylene glycol monomethyl ether acetate so as to achieve a solid content concentration of 30%. A cation-exchange resin and an anion-exchange resin were each added to the diluted polymer in an amount equal to the solid content, and the resultant mixture was stirred for four hours. The ion-exchange resins were filtered to thereby prepare a polymer (C) solution.

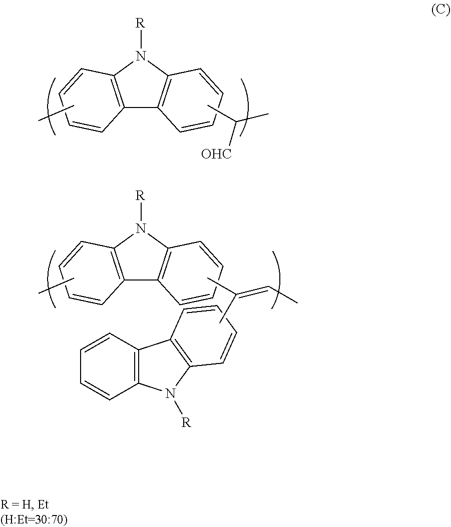

### Synthesis Example 4

(Synthesis of Polymer (D))(Cz/1Na/Glyoxal=50/50/50)

A 200-mL four-necked flask equipped with a stirring bar and a cooling tube was charged with 11.00 g (65.79 mmol) of carbazole (available from Tokyo Chemical Industry Co., Ltd.), 9.48 g (65.79 mmol) of 1-naphthol (available from Tokyo Chemical Industry Co., Ltd.), 5.87 g (39.47 mmol) of glyoxal (39% aqueous solution, about 8.8 mol/L, available from Tokyo Chemical Industry Co., Ltd.), 0.75 g (3.95 mmol) of p-toluenesulfonic acid monohydrate (available from Tokyo Chemical Industry Co., Ltd.), and 29.83 g of 1,4-dioxane (Cica special grade, available from Kanto Chemical Co., Inc.), and the resultant mixture was heated to 90° C. and stirred at 90° C. for 21 hours. After being cooled to 60° C. or lower, the mixture was diluted with 56.94 g of tetrahydrofuran (special grade, available from Kanto Chemical Co., Inc.), and the mixture was cooled to 30° C. or lower. The resultant reaction mixture was added dropwise to 1 L of a mixed solvent of methanol (special grade, available from Kanto Chemical Co., Inc.)/water (5/5), to thereby precipitate a polymer. The resultant precipitate was separated by filtration, and the residue was washed three times with 250 mL of a mixed solvent of methanol/water (5/5) and dried under vacuum, to thereby produce a polymer. The molecular weight of the polymer was measured by GPC (in terms of standard polystyrene). As a result, the polymer was found to have a weight average molecular weight (Mw) of 1,053 (yield: 66.3%). The polymer has a repeating unit structure of the following Formula (D). The resultant polymer was diluted with propylene glycol monomethyl ether acetate so as to achieve a solid content concentration of 30%. A cation-exchange resin and an anion-exchange resin were each added to the diluted polymer in an amount equal to the solid content, and the resultant mixture was stirred for four hours. The ion-exchange resins were filtered to thereby prepare a polymer (D) solution.

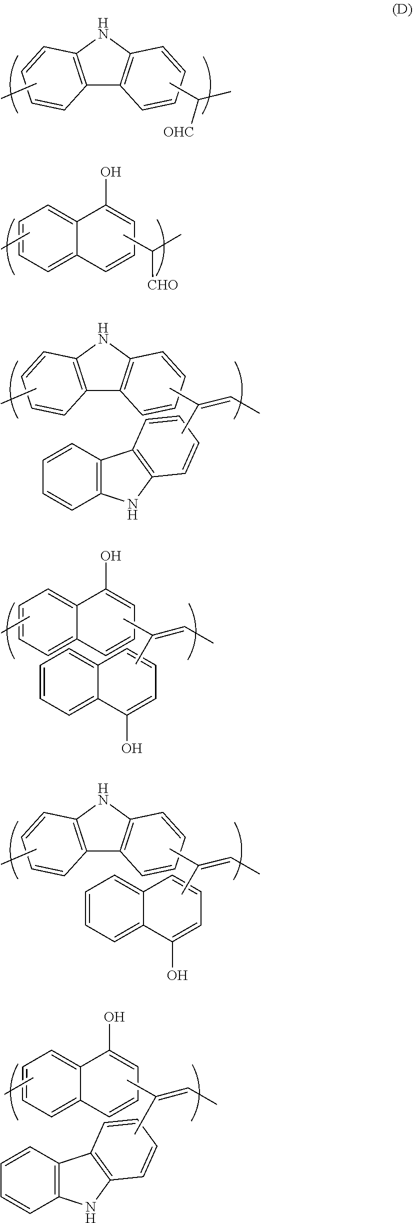

### Synthesis Example 5

(Synthesis of Polymer (E))(2,3-DMP/Glutalaldehyde=100/30)

A 200-mL four-necked flask equipped with a stirring bar and a cooling tube was charged with 17.00 g (139.15 mmol) of 2,3-dimethylphenol (available from Tokyo Chemical Industry Co., Ltd.), 8.37 g (341.75 mmol) of glutaraldehyde (about 50% aqueous solution, available from Tokyo Chemical Industry Co., Ltd.), 0.80 g (4.2 mmol) of p-toluenesulfonic acid monohydrate (available from Tokyo Chemical Industry Co., Ltd.), and 59.28 g of 1,4-dioxane, and the resultant mixture was heated to 90° C. and stirred at 90° C. for 97.5 hours. The reaction solution was cooled to 30° C. or lower, and then diluted with 21.18 g of tetrahydrofuran (special grade, available from Kanto Chemical Co., Inc.). The resultant reaction mixture was added dropwise to 950 mL of a mixed solvent of methanol (special grade, available from Kanto Chemical Co., Inc.)/water (7/3), to thereby precipitate a polymer. The resultant precipitate was separated by filtration, and the residue was washed three times with 240 mL of a mixed solvent of methanol/water (7/3) and dried under vacuum, to thereby produce a polymer. The molecular weight of the polymer was measured by GPC (in terms of standard polystyrene). As a result, the polymer was found to have a weight average molecular weight (Mw) of 1,920 (yield: 56.9%). The polymer has a repeating unit structure of the following Formula (E). The resultant polymer was diluted with propylene glycol monomethyl ether acetate so as to achieve a solid content concentration of 30%. A cation-exchange resin and an anion-exchange resin were each added to the diluted polymer in an amount equal to the solid content, and the resultant mixture was stirred for four hours. The ion-exchange resins were filtered to thereby prepare a polymer (E) solution.

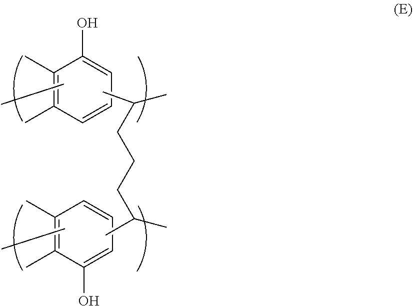

### Synthesis Example 6

(Synthesis of Polymer (F))(Cz/EHA=50/50)

A 200-mL four-necked flask equipped with a stirring bar and a cooling tube was charged with 12.00 g (71.77 mmol) of carbazole (available from Tokyo Chemical Industry Co., Ltd.), 9.21 g (71.77 mmol) of 2-ethylhexanal (available from Tokyo Chemical Industry Co., Ltd.), 1.40 g (14.36 mmol) of methanesulfonic acid (available from Tokyo Chemical Industry Co., Ltd.), and 49.13 g of propylene glycol monomethyl ether acetate, and the resultant mixture was heated to 120° C. and stirred at 120° C. for 38.5 hours. The reaction solution was cooled to 30° C. or lower, and the resultant reaction mixture was added dropwise to 640 mL of methanol (special grade, available from Kanto Chemical Co., Inc.), to thereby precipitate a polymer. The resultant precipitate was separated by filtration, and the residue was washed three times with 160 mL of methanol and dried under vacuum, to thereby produce a polymer. The molecular weight of the polymer was measured by GPC (in terms of standard polystyrene). As a result, the polymer was found to have a weight average molecular weight (Mw) of 19,476 (yield: 72.6%). The polymer has a repeating unit structure of the following Formula (F). The resultant polymer was diluted with propylene glycol monomethyl ether acetate so as to achieve a solid content concentration of 30%. A cation-exchange resin and an anion-exchange resin were each added to the diluted polymer in an amount equal to the solid content, and the resultant mixture was stirred for four hours. The ion-exchange resins were filtered to thereby prepare a polymer (F) solution.

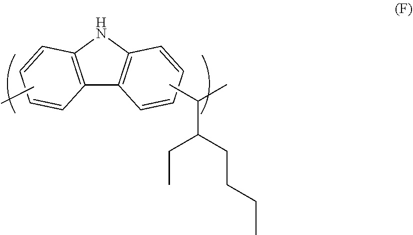

### Example 1

2.94 g of the resin prepared in Synthesis Example 1 was mixed with 0.82 g of propylene glycol monomethyl ether containing 2% pyridinium p-hydroxybenzenesulfonate, 0.16 g of TMOM-BP (available from Honshu Chemical Industry Co., Ltd., crosslinking agent), 0.08 g of propylene glycol monomethyl ether acetate containing 1% surfactant (available from DIC Corporation, product name: MEGAFACE [trade name] R-40, fluorine-containing surfactant), 1.00 g of propylene glycol monomethyl ether, 1.39 g of propylene glycol monomethyl ether acetate, and 3.60 g of cyclohexanone. Thereafter, the mixture was filtered with a polytetrafluoroethylene-made microfilter (pore size: 0.1 μm), to thereby prepare a resist underlayer film-forming composition solution.

### Example 2

2.82 g of the resin prepared in Synthesis Example 1 was mixed with 0.98 g of propylene glycol monomethyl ether containing 2% pyridinium p-hydroxybenzenesulfonate, 0.2 g of tetramethoxymethyl glycoluril, 0.08 g of propylene glycol monomethyl ether acetate containing 1% surfactant (available from DIC Corporation, product name: MEGAFACE [trade name] R-40, fluorine-containing surfactant), 0.84 g of propylene glycol monomethyl ether, 1.49 g of propylene glycol monomethyl ether acetate, and 3.60 g of cyclohexanone. Thereafter, the mixture was filtered with a polytetrafluoroethylene-made microfilter (pore size: 0.1 μm), to thereby prepare a resist underlayer film-forming composition solution.

### Example 3

1.79 g of the resin prepared in Synthesis Example 2 was mixed with 0.23 g of propylene glycol monomethyl ether containing 2% pyridinium p-hydroxybenzenesulfonate, 0.05 g of TMOM-BP (available from Honshu Chemical Industry Co., Ltd., crosslinking agent), 0.05 g of propylene glycol monomethyl ether acetate containing 1% surfactant (available from DIC Corporation, product name: MEGAFACE [trade name] R-40, fluorine-containing surfactant), 0.68 g of propylene glycol monomethyl ether, 0.41 g of propylene glycol monomethyl ether acetate, and 1.80 g of cyclohexanone. Thereafter, the mixture was filtered with a polytetrafluoroethylene-made microfilter (pore size: 0.1 μm), to thereby prepare a resist underlayer film-forming composition solution.

### Example 4

1.50 g of the resin prepared in Synthesis Example 3 was mixed with 0.23 g of propylene glycol monomethyl ether containing 2% pyridinium p-hydroxybenzenesulfonate, 0.05 g of TMOM-BP (available from Honshu Chemical Industry Co., Ltd., crosslinking agent), 0.05 g of propylene glycol monomethyl ether acetate containing 1% surfactant (available from DIC Corporation, product name: MEGAFACE [trade name] R-40, fluorine-containing surfactant), 0.68 g of propylene glycol monomethyl ether, 1.76 g of propylene glycol monomethyl ether acetate, and 0.75 g of cyclohexanone. Thereafter, the mixture was filtered with a polytetrafluoroethylene-made microfilter (pore size: 0.1 μm), to thereby prepare a resist underlayer film-forming composition solution.

### Example 5

1.37 g of the resin prepared in Synthesis Example 3 was mixed with 0.23 g of propylene glycol monomethyl ether containing 2% pyridinium p-hydroxybenzenesulfonate, 0.08 g of tetramethoxymethyl glycoluril, 0.04 g of propylene glycol monomethyl ether acetate containing 1% surfactant (available from DIC Corporation, product name: MEGAFACE [trade name] R-40, fluorine-containing surfactant), 0.50 g of propylene glycol monomethyl ether, 1.76 g of propylene glycol monomethyl ether acetate, and 0.84 g of cyclohexanone. Thereafter, the mixture was filtered with a polytetrafluoroethylene-made microfilter (pore size: 0.1 μm), to thereby prepare a resist underlayer film-forming composition solution.

### Example 6

1.76 g of the resin prepared in Synthesis Example 4 was mixed with 0.41 g of propylene glycol monomethyl ether containing 2% pyridinium p-hydroxybenzenesulfonate, 0.08 g of tetramethoxymethyl glycoluril, 0.04 g of propylene glycol monomethyl ether acetate containing 1% surfactant (available from DIC Corporation, product name: MEGAFACE [trade name] R-40, fluorine-containing surfactant), 0.95 g of propylene glycol monomethyl ether, and 1.76 g of propylene glycol monomethyl ether acetate. Thereafter, the mixture was filtered with a polytetrafluoroethylene-made microfilter (pore size: 0.1 μm), to thereby prepare a resist underlayer film-forming composition solution.

### Comparative Example 1

2.87 g of the resin prepared in Synthesis Example 5 was mixed with 0.77 g of propylene glycol monomethyl ether containing 1% pyridinium p-toluenesulfonate, 0.08 g of tetramethoxymethyl glycoluril, 0.08 g of propylene glycol monomethyl ether acetate containing 1% surfactant (available from DIC Corporation, product name: MEGAFACE [trade name] R-40, fluorine-containing surfactant), 1.98 g of propylene glycol monomethyl ether, and 4.23 g of propylene glycol monomethyl ether acetate. Thereafter, the mixture was filtered with a polytetrafluoroethylene-made microfilter (pore size: 0.1 μm), to thereby prepare a resist underlayer film-forming composition solution.

### Comparative Example 2

2.96 g of the resin prepared in Synthesis Example 6 was mixed with 0.77 g of propylene glycol monomethyl ether containing 1% pyridinium p-toluenesulfonate, 0.08 g of tetramethoxymethyl glycoluril, 0.08 g of propylene glycol monomethyl ether acetate containing 1% surfactant (available from DIC Corporation, product name: MEGAFACE [trade name] R-40, fluorine-containing surfactant), 1.98 g of propylene glycol monomethyl ether, and 4.14 g of propylene glycol monomethyl ether acetate. Thereafter, the mixture was filtered with a polytetrafluoroethylene-made microfilter (pore size: 0.1 μm), to thereby prepare a resist underlayer film-forming composition solution.

### Test for Elution in Photoresist Solvent

Each of the resist underlayer film-forming compositions prepared in Examples 1 to 6 and Comparative Examples 1 and 2 was applied onto a silicon wafer with a spinner. Thereafter, the composition was baked on a hot plate at 240° C. for one minute, to thereby form a resist underlayer film (thickness: 0.2 μm). The resist underlayer film was immersed in a solvent used for a photoresist solution; i.e., PGME/PGMEA mixed solvent (mixing ratio by mass: 70/30), and the film was found to be insoluble in the solvent. The results are shown as “∘” in Table 1 below.

### Test for Optical Parameters

Each of the resist underlayer film-forming compositions prepared in Examples 1 to 6 and Comparative Examples 1 and 2 was applied onto a silicon wafer with a spinner. Thereafter, the composition was baked on a hot plate at a temperature shown in Table 1 below for one minute, to thereby form a resist underlayer film (thickness: 0.2 μm). Subsequently, the refractive index (n value) and attenuation coefficient (k value) of the resist underlayer film were measured at a wavelength of 193 nm with an optical ellipsometer (VUV-VASE VU-302, available from J. A. Woollam). The results are shown in Table 1 below. The k value at a wavelength of 193 nm is preferably 0.1 or more in view that the resist underlayer film has a sufficient anti-reflective function.

### Measurement of Dry Etching Rate

Each of the resist underlayer film-forming compositions prepared in Examples 1 to 6 and Comparative Examples 1 and 2 was used to form a resist underlayer film on a silicon wafer in the same manner as described above. The dry etching rate of the resist underlayer film was measured with an RIE system available from SAMCO Inc. under the condition that CF₄ was used as a dry etching gas. The dry etching rate of each resist underlayer film was calculated by taking the dry etching rate of the resist underlayer film of Example 5 as 1.00. The results are shown in Table 1 below as “Relative dry etching rate.” As compared with the case of Comparative Example 1, the resist underlayer film formed from each of the resist underlayer film-forming compositions prepared in Examples 1 to 6 exhibited a sufficiently low dry etching rate. The results indicated that a substrate is readily processed by using, as a mask, the resist underlayer film-forming composition of the present invention.

### Measurement of Hardness

Each of the resist underlayer film-forming compositions prepared in Examples 1 to 6 and Comparative Examples 1 and 2 was applied onto a silicon wafer with a spinner. Thereafter, the composition was baked on a hot plate at 240° C. for one minute, to thereby form a resist underlayer film (thickness: 0.2 μm). The hardness of the resist underlayer film was measured by performing a nanoindentation test with a nanoindenter available from TOYO Corporation. Each of the resist underlayer films of Examples 1 to 6 was found to have a hardness of 0.50 GPa or more and a denser structure. The results indicated that the resist underlayer film is beneficial for use in substrate processing by etching.

### Evaluation of Embedding Property

Embedding property was determined by using an SiO₂ substrate having a thickness of 200 nm and having a dense patterned area (trench width: 50 nm, pitch: 100 nm). Each of the resist underlayer film-forming compositions prepared in Examples 1 to 6 and Comparative Examples 1 and 2 was applied onto the aforementioned substrate, and then baked at 240° C. for 60 seconds, to thereby form a resist underlayer film (about 200 nm). For evaluation of the flattening property of the substrate, the substrate was observed with a scanning electron microscope (S-4800) available from Hitachi High-Technologies Corporation, to thereby determine whether or not the interior of the pattern was filled with the resist underlayer film-forming composition. Favorable results were obtained in Examples 1 to 6.

TABLE 1

| | | | | | | Embedding |
|---|---|---|---|---|---|---|
| | Polymer | Elution test | n/k | E.R. | Hardness | Property |
| Example 1 | Polymer (A) | ◯ | 1.42/0.42 | 0.89 | 0.56 | ◯ |
| Example 2 | Polymer (A) | ◯ | 1.49/0.39 | 0.97 | 0.53 | ◯ |
| Example 3 | Polymer (B) | ◯ | 1.49/0.35 | 0.97 | 0.57 | ◯ |
| Example 4 | Polymer (C) | ◯ | 1.48/0.37 | 0.96 | 0.59 | ◯ |
| Example 5 | Polymer (C) | ◯ | 1.52/0.36 | 1.00 | 0.55 | ◯ |
| Example 6 | Polymer (D) | ◯ | 1.41/0.38 | 0.95 | 0.50 | ◯ |
| Comparative | Polymer (E) | ◯ | 1.38/0.64 | 1.04 | 0.21 | ◯ |
| Example 1 | | | | | | |
| Comparative | Polymer (F) | ◯ | 1.55/0.24 | 0.98 | 0.20 | ◯ |
| Example 2 | | | | | | |

* E.R. = Relative etching rate

### INDUSTRIAL APPLICABILITY

According to the present invention, there are provided a resist underlayer film-forming composition that exhibits a high etching resistance, a favorable dry etching rate ratio and optical constant, and can form a film exhibiting a good coatability even to a so-called uneven substrate, providing a small difference in film thickness after embedding, and having planarity and a superior hardness; a polymer suitable for use in the resist underlayer film-forming composition; a resist underlayer film formed from the resist underlayer film-forming composition; and a method of producing a semiconductor device.

1. A resist underlayer film-forming composition comprising a reaction product between a compound of the following Formula (1) or (2) and a compound of the following Formula (3), and a solvent: 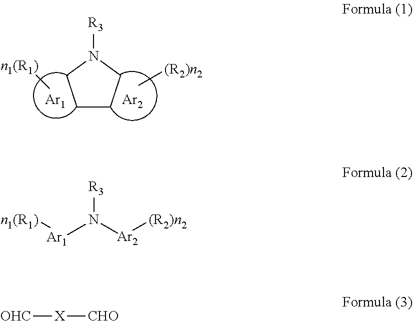
(in Formula (1) or (2), Ar₁ and Ar₂ are each independently a benzene ring or naphthalene ring substitutable with R₁ or R₂; R₁ and R₂ are each a hydrogen atom, a halogen atom, a nitro group, an amino group, a hydroxyl group, a C₁₋₁₀ alkyl group, a C₂₋₁₀ alkenyl group, a C₆₋₄₀ aryl group, or any combination of these possibly containing an ether bond, a ketone bond, or an ester bond; R₃ is a hydrogen atom, a C₁₋₁₀ alkyl group, a C₂₋₁₀ alkenyl group, a C₂₋₁₀ alkynyl group, a C₆₋₄₀ aryl group, or any combination of these possibly containing an ether bond, a ketone bond, or an ester bond; and n₁ and n₂ are each an integer of 1 to 3 when Ar₁ and Ar₂ are each a benzene ring, or an integer of 1 to 5 when Ar₁ and Ar₂ are each a naphthalene ring; and
in Formula (3), X is a single bond, a saturated or unsaturated linear or cyclic organic group having a carbon atom number of 1 to 30 and possibly containing a nitrogen atom, an oxygen atom, or a sulfur atom, or a C₆₋₃₀ arylene group).

2. The resist underlayer film-forming composition according to claim 1, wherein, in Formula (1) or (2), Ar₁ and Ar₂ are each a benzene ring.

3. The resist underlayer film-forming composition according to claim 1, wherein, in Formula (1), R₁ and R₂ are each a hydrogen atom.

4. The resist underlayer film-forming composition according to claim 1, wherein, in Formula (3), X is a single bond, or a saturated or unsaturated linear or cyclic organic group having a carbon atom number of 1 to 30 and possibly containing a nitrogen atom.

5. The resist underlayer film-forming composition according to claim 1 wherein, in Formula (3), X is a single bond.

6. The resist underlayer film-forming composition according to claim 1, wherein the composition comprises a reaction product between two or more compounds of Formula (1) or (2) and a compound of Formula (3).

7. The resist underlayer film-forming composition according to claim 1, wherein the composition comprises a reaction product between a compound of Formula (1) or (2), an additional aromatic compound other than the compound of Formula (1) or (2) and a compound of Formula (3).

8. The resist underlayer film-forming composition according to claim 1, wherein the composition further comprises a crosslinking agent.

9. The resist underlayer film-forming composition according to claim 1, wherein the composition further comprises an acid and/or an acid generator.

10. The resist underlayer film-forming composition according to claim 1, wherein the solvent has a boiling point of 160° C. or higher.

11. A resist underlayer film characterized by being a baked product of a coating film formed from the resist underlayer film-forming composition according to claim 1.

12. A method of producing a semiconductor device comprising:
a step of forming, on a semiconductor substrate, a resist underlayer film from the resist underlayer film-forming composition according to claim 1;
a step of forming a resist film on the formed resist underlayer film;
a step of irradiating the formed resist film with light or electron beams, and developing the resist film, to thereby form a resist pattern;
a step of etching the resist underlayer film with the formed resist pattern, to thereby form a pattern on the resist underlayer film; and
a step of processing the semiconductor substrate with the patterned resist underlayer film.
